(19) United States
(12) Patent Application Publication
(10) Pub. No.: US 2015/0043188 A1
(43) Pub. Date: Feb. 12, 2015

(54) Method For Manufacturing A Printed Circuit Board, Printed Circuit Board And Rear View Device

(71) Applicant: SMR Patents S.A.R.L., Luxembourg (LU)

(72) Inventor: Andreas Herrmann, Winnenden-Baach (DE)

(73) Assignee: SMR PATENTS S.A.R.L., Luxembourg (LU)

(21) Appl. No.: 14/452,640

(22) Filed: Aug. 6, 2014

(30) Foreign Application Priority Data
Aug. 7, 2013 (DE) 102013108535.0

(51) Int. Cl. H05K 1/14; H05K 3/10; B60R 1/12

(52) U.S. Cl. CPC H05K 1/142; B60R 1/12; H05K 3/10
USPC 361/803; 29/830

(57) ABSTRACT

The invention relates to a method for manufacturing a printed circuit board (10) having a substrate (2) and an electric circuit (8), in particular for a rear view device of a motor vehicle, the method comprising the following steps:
manufacturing a plurality of substrate parts (2a, 2b); and
selecting at least two of the substrate parts (2a, 2b), and
connecting the selected substrate parts (2a, 2b) and providing the connected substrate parts (2a, 2b) with the circuit (8).

This application claim priority from DE 10 2013 108 535.0, filed Aug. 7, 2013, which is incorporated herein.

### BACKGROUND

The present invention relates to a method for manufacturing a printed circuit board having a substrate and an electric circuit, in particular a printed circuit board for a rear view device of a motor vehicle, a printed circuit board manufactured in said manner and a rear view device of a motor vehicle including said printed circuit board.

The shape, dimensions and attached electronic components of known printed circuit boards being manufactured in large volume are adapted to their application. The electric circuit or circuits to be used on or in the boards and their layout are tailor-made, which permits a compact design of the mounting place. It is therefore difficult to use these printed circuit boards for another application or in another place. Consequently, a plurality of printed circuit boards need to be planned and made available for the various applications.

Even for identical assemblies, such as a rear view device of a motor vehicle, various printed circuit boards, e. g. having different dimensions, are required for controlling electronic components of the rear view device, depending on the type and electrical components of the rear view device, which is costly.

A method for selectively metallising a substrate is known from EP 2 476 723 A1. Laser direct structuring techniques enable the application of circuits in the desired layout on three-dimensional substrates.

Laser welding of two plastic members to be joined is described in WO2013/026816 A1.

DE 101 05 621 A1 discloses an electric circuit board including a plurality of conductor paths arranged on at least one of its main surfaces and a plurality of connecting elements assigned to them for electrically contacting at least one additional electric circuit board.

An electronic control unit for controlling electrical assemblies of motor vehicle doors with differing equipment is known from DE 199 51 916 C1. Here, circuit boards comprising electrical structures are to be assembled depending on the equipment.

DE 296 23 310 U1 describes a roof module especially for motor vehicles which is connected to an onboard power supply system in order to be linked to other remotely provided apparatuses, and which comprises a plurality of functional units, wherein the interfaces required for the connection to the onboard power supply system are part of one single main printed circuit board fixed in the housing of the roof module, and the main printed circuit board comprises at least the functional elements necessary for carrying out the internal control processes and for establishing the internal links of at least two of the functional units.

It would be advantageous if printed circuit boards could be manufacture more efficiently.

### SUMMARY OF THE INVENTION

It is the purpose of the present invention to provide a method for manufacturing a printed circuit board having a substrate and an electric circuit that is simple and cost-efficient and expands the range of applications of the manufactured printed circuit board.

This purpose is fulfilled by the features of Claim 1, in which the manufacturing method comprises:
manufacturing a plurality of substrate parts;
selecting and connecting at least two of the substrate parts; and
providing the connected substrate parts with an electrical circuit.

Claims 2 to 8 describe preferred methods according to the invention. For example, the first substrate part may have a fitting or portion that is keyed or complementary to a fitting or portion of the second substrate part.

Claims 9, 10 and 11 relate to a printed circuit board manufactured by a method according to the invention, and

Claims 12 and 13 relate to a rear view device including said printed circuit board.

A printed circuit board in the spirit of the invention is any circuit carrier and does not only comprise essentially two-dimensional but also three-dimensional designs. Electric circuits respectively circuit parts in the spirit of the invention are conductive structures which can be arranged on and/or in the circuit carrier. The printed circuit board according to the invention may comprise two or more substrate parts. Preference is given to the provision of different standard substrate parts which can be selected and assembled on a modular basis. The printed circuit board according to the invention can be suited in particular for being used in an arrangement in or at a rear view device of a motor vehicle.

Known circuit parts can be arranged on or at the associated substrate parts prior to their assembly, however, according to the invention a circuit can be arranged on or at the substrate part structure after the assembly. The circuit parts of the assembled substrate parts are functionally connected and can interact with each other. Optionally, the substrate parts provided with the circuit parts are designed such that only those parts can be connected which interact meaningfully.

Contacts of one circuit part which are raised from one substrate part can be arranged such that if a mechanical connection to another substrate part including a circuit part exists, a conductive contact is automatically established between the contacts. Alternatively, the circuit parts of various substrate parts can be connected by means of other known techniques, e.g. using solder straps, plugs, wires, etc.

In one embodiment according to the invention the circuit is applied by laser direct structuring after having been assembled into a printed circuit board. By arranging the circuit after the assembly it can be arranged continuously by laser direct structuring, whereby a subsequent functional connection of conductive structures on the other substrate parts can be omitted.

The substrate parts can be made from different or the same materials, in particular from plastic and/or ceramics.

Optionally, one or more substrate parts have a receiving element for an electrical load, such as a lamp. A power supply is also connectable to the circuit parts on the substrate parts.

Further features and advantages can be derived from the following schematic drawing, wherein the embodiments of the invention are shown in the drawing by way of example and are in no way restrictive.

### BRIEF DESCRIPTION OF THE DRAWINGS

FIG. 1 illustrates a first printed circuit board body;

FIG. 2 illustrates a second printed circuit board body; and

FIG. 3 illustrates a printed circuit board according to the invention

### DETAILED DESCRIPTION OF THE INVENTION

The present invention will now be described with occasional reference to the specific embodiments of the invention. This invention may, however, be embodied in different forms and should not be construed as limited to the embodiments set forth herein. Rather, these embodiments are provided so that this disclosure will be thorough and complete, and will fully convey the scope of the invention to those skilled in the art.

Unless otherwise defined, all technical and scientific terms used herein have the same meaning as commonly understood by one of ordinary skill in the art to which this invention belongs. The terminology used in the description of the invention herein is for describing particular embodiments only and is not intended to be limiting of the invention. As used in the description of the invention and the appended claims, the singular forms “a,” “an,” and “the” are intended to include the plural forms as well, unless the context clearly indicates otherwise.

Unless otherwise indicated, all numbers expressing quantities of dimensions such as length, width, height, and so forth as used in the specification and claims are to be understood as being modified in all instances by the term “about.” Accordingly, unless otherwise indicated, the numerical properties set forth in the specification and claims are approximations that may vary depending on the desired properties sought to be obtained in embodiments of the present invention. Notwithstanding that the numerical ranges and parameters setting forth the broad scope of the invention are approximations, the numerical values set forth in the specific examples are reported as precisely as possible. Any numerical values, however, inherently contain certain errors necessarily resulting from error found in their respective measurements.

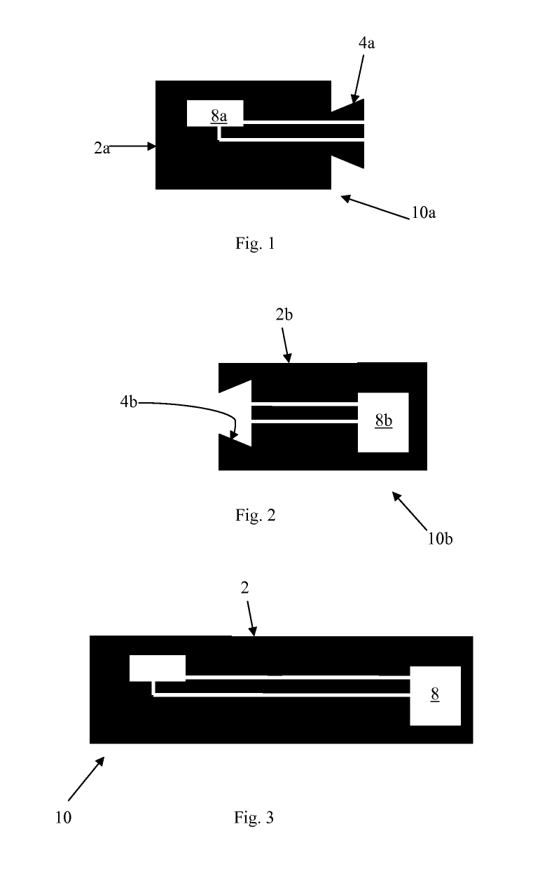

FIG. 1 shows a first printed circuit board body 10a having a first substrate part 2a including coupling means 4a and a first circuit part 8a, which are already arranged on the first substrate part 2a in this exemplary embodiment. According to the invention, however, it can be arranged by known techniques even after the assembly of two or more substrate parts.

The first printed circuit board body 10a shown in the embodiment of FIG. 1 comprises only one coupling means 4a, but it can also comprise additional coupling means and/or corresponding receiving means such that any number of printed circuit board bodies having the same, similar or different layouts can be connected with each other.

FIG. 2 shows a second printed circuit board body 10b with a second substrate part 2b including receiving means 4b and a second circuit part 8b. The receiving means 4b of the second printed circuit board body 10b is designed such that it can be detachably connected with the receiving means 4a of the first printed circuit board body 10a in a positive locking way. A complementary shaped key or portion is one example of a positive locking coupling mode.

When the first printed circuit board body 10a is joined with the second printed circuit board body 10b, the coupling means 4a and the receiving means 4b engage with each other such that they are positively locked with each other. As an alternative to this embodiment the coupling means 4a and the receiving means 4b can have different forms and do not need to completely engage with each other. In particular, the printed circuit board bodies 10a, 10b can contact each other only partly or only at the contact points of the coupling means and the receiving means 4a, 4b.

FIG. 3 shows a printed circuit board 10, wherein the printed circuit board 10 comprises the first printed circuit board body 10a and the second printed circuit board body 10b. The first and the second printed circuit board bodies 10a, 10b are positively locked with each other by the coupling means 4a and the receiving means 4b of the two substrate parts 2b, 2b. Moreover, both circuit parts 8a, 8b are conductively connected with each other. There is consequently a printed circuit board 10 with a substrate 2 including two substrate parts 2a, 2b and one circuit 8 including two circuit parts 8a, 8b.

In one exemplary embodiment the second printed circuit board body 10b can provide a power supply, whereas the first printed circuit board body 10a can be provided with loads such as sensors, motors, lamps or corresponding control units, which are to be connected to the power supply. In the exemplary case of a rear view device for a motor vehicle, a mirror can have a larger or smaller number of electrical loads, depending on the vehicle's trim level. A power supply on a printed circuit board body can be designed such that it can be used for two or more trim levels, i.e. power can be supplied to a varying number of loads.

Furthermore, a plurality of printed circuit board bodies, in particular each including at least one coupling means and at least one receiving means, can have a circuit with a continuously conductive structure, which is preferably available both at the coupling means and the receiving means. Additional printed circuit board bodies attached to it can thus be connected to this continuously conductive structure. For example, a timing and/or data line and/or a power supply can be used in the conductive structures of a plurality of printed circuit board bodies. The power supply provided by one printed circuit board body can e. g. be used for loads on a plurality of printed circuit board bodies.

An optional design of the invention has different coupling and receiving means such that only those coupling and receiving means can be connected with each other which create a useful connection of the conductive structures.

In manufacturing a rear view device according to the invention, especially a motor vehicle rear view mirror or a display, a housing is provided. This can be a known housing of a vehicle rear view mirror. Then a first printed circuit board body 10a having at least one coupling means 4a and a second printed circuit board body 10b having at least one receiving means 4b are provided. The first printed circuit board body 10a is fastened by means of the coupling means 4a to the second printed circuit board body 10b by means of the receiving means 4b. This fastening can be a releasable or a permanent connection. Furthermore, a circuit 8 is fastened to the first printed circuit board body 10a by means of a first circuit part 8a and a second circuit part 8b is fastened to the second printed circuit board body 10b by means of a second circuit part 8b. The circuit can optionally be arranged on a first substrate part 2a of the first printed circuit board body 10a and on a second substrate part 2b of the second printed circuit board body 102 by way of laser direct structuring. As mentioned above, the circuit 8 can be an electrically conductive structure. Electric circuits and/or loads can also be arranged on the printed circuit board bodies.

In some embodiments, at least a portion of the electrical circuit 8 extends to an edge of the a substrate part, and includes one or more contact surfaces for making electrical connections to other portions of the electrical circuit 8 that are on an adjacent substrate portion. For example, the electrical connections of the circuit 8 may pass through the coupling means area of the substrates. In this way, the complete circuit may span multiple substrate parts.

The principle and mode of operation of the invention has been described in certain embodiments. However, it should be noted that the invention may be practiced in other embodiments than those specifically illustrated and described without departing from its scope.

What is claimed is:

1. A method for manufacturing a printed circuit board for a rear view device of a motor vehicle, the method comprising:
manufacturing a plurality of substrate parts;
selecting and connecting at least two of the substrate parts; and
providing the connected substrate parts with a circuit.

2. The method according to claim 1, wherein the substrate parts are formed from plastic or from ceramics.

3. The method according to claim 2, wherein the substrate parts are formed from plastic substrate parts in an injection moulding process.

4. The method according to claim 3, wherein the substrate parts are formed as standardized components, the standardized components having at least two different forms.

5. The method according to claim 1, wherein a first substrate part is connected to at least a second substrate part through at least one coupling means selected from frictional connection, double friction surfaces, positive locking, complementary keyed portions, adhesive force, or laser welding.

6. The method according to claim 5, wherein first substrate parts are each formed with at least one coupling means and second substrate parts are each formed with at least one receiving means to receive a coupling means of a first substrate part.

7. The method according to one claim 1, wherein the circuit is applied to the substrate through a film, a coating, a selective metallisation and/or laser direct structuring.

8. The method according to claim 1, wherein for standard components, the substrate parts to be connected are selected depending on the number of standard components of each form and on the circuit.

9. A printed circuit board manufactured according to claim 1.

10. A printed circuit board manufactured according to claim 4.

11. A printed circuit board manufactured according to claim 6.

12. A rear view device for a vehicle, comprising:
a housing;
at least one printed circuit board according to claim 9;
at least one electrical load operatively interacting with the printed circuit board, and
at least one power supply operatively interacting with the printed circuit board.

13. The rear view device according to claim 8, wherein the electrical load is at least one load selected from a lamp, a sensor, a camera, a motor, a heater and/or a control unit.
